(19) United States
(12) Patent Application Publication
(10) Pub. No.: US 2008/0261358 A1
(43) Pub. Date: Oct. 23, 2008

(54) Manufacture of Lateral Semiconductor Devices

(75) Inventor: Jan Sonsky, Leuven (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/815,763

(22) PCT Filed: Feb. 6, 2006
(86) PCT No.: PCT/IB2006/050377

§ 371 Date: Oct. 1, 2007

(30) Foreign Application Priority Data
Feb. 7, 2005 (EP) 05100846.4

(51) Int. Cl. H01L 21/336

(52) U.S. Cl. 438/197; 438/286; 257/E21.616

(57) ABSTRACT

A method of manufacturing a lateral semiconductor device comprising a semiconductor body (2) having top and bottom major surfaces (2a, 2b), the body including a drain drift region (6a) of a first conductivity type. The method includes the steps of forming a vertical access trench (20) in the semiconductor body which extends from its top major surface (2a) and has a bottom and sidewalls; forming at least one horizontal trench (16) extending within the drain drift region (6a) which extends from a sidewall of the vertical trench (20) in the finished device; and forming a RESURF inducing structure (22) extending within the at least one horizontal trench. In this way, vertically separated lateral RESURF inducing structures are formed without encountering problems associated with known techniques for forming RESURF structures.

The present invention relates to methods of manufacturing a lateral semiconductor device, for example an insulated gate field-effect power transistor (commonly termed a “MOSFET”). The invention also relates to semiconductor devices manufactured by such a method.

Lateral semiconductor devices are mainly employed in integrated circuits, rather than vertical devices, as a connection to the drain region of a lateral device can be made directly at the top surface of the semiconductor body. In contrast, in a vertical device, the drain region is typically formed at the bottom of the structure, and a separate peripheral contact region extending from the surface to the depth of the buried drain region must be provided, which may substantially increase the total on-resistance of the device and complicate its fabrication.

The breakdown voltage of simple p-n junction is dependent on the doping levels of the p and n regions. A number of so-called RESURF (“reduced surface field”) inducing structures have been developed which serve to enhance the breakdown voltage of a p-n junction without a reduction in the doping levels of the p and n regions. These structures comprise dielectric RESURF, field plate, and multiple RESURF (or “superjunction”) configurations, for example.

Depending on the form of RESURF inducing structure employed, devices may be manufactured which are applicable across a broad voltage range from 50 up to 1000V or more. However, in lateral devices using dielectric RESURF or multiple RESURF structures, only part of the device width is actually used for current conduction. The tranches of dielectric or compensatingly doped regions running in parallel with the conduction channels do not contribute to the conduction. A device including a typical field plate structure will only have a single conduction channel, with a first field plate provided on top of the semiconductor body, and a second over the opposite surface of the semiconductor body.

U.S. Pat. No. 6,555,873 discloses a high-voltage transistor including a multi-layered extended drain structure which comprises extended drift regions separated from field plate members by one or more dielectric layers.

US-A-2003/0102507 describes a semiconductor device in which an extended drain region of a first conductivity type includes a plurality of buried layers, each formed by burying an impurity layer of a second conductivity type. The buried layers extend substantially parallel to a substrate surface, with an interval therebetween in the depth direction.

The present invention seeks to provide an improved method of manufacturing a lateral semiconductor device including a RESURF inducing structure in its drain drift region.

The present invention provides a method of manufacturing a lateral semiconductor device comprising a semiconductor body having top and bottom major surfaces, the body including a drain drift region of a first conductivity type, wherein the method includes the steps of:

(a) forming a vertical access trench in the semiconductor body which extends from its top major surface and has a bottom and sidewalls;

(b) forming at least one horizontal trench extending within the drain drift region, which extends from a sidewall of the access trench in the finished device; and

(c) forming a RESURF inducing structure extending within the at least one horizontal trench.

The claimed method facilitates the formation of vertically separated lateral RESURF inducing structures, whilst avoiding problems associated with known techniques for forming RESURF structures.

References herein to “vertical” and “horizontal” directions denote directions extending substantially perpendicular to, and substantially parallel to, the top and bottom major surfaces of the semiconductor body, respectively.

A device manufactured according to a method of the invention has multiple conduction channels stacked on top of one another with horizontal trenches in-between containing structures configured to create RESURF effects. This leads to a substantial reduction in on-resistance for a given breakdown voltage in comparison with an equivalent device having only a single horizontal channel.

In a preferred embodiment of the method of the invention, a plurality of vertically and horizontally separated horizontal trenches are formed in step (b). These trenches may be in the form of horizontally extending pillars or columns. This may produce a further reduction in the on-resistance of a device, by increasing the cross-sectional area of the drain drift region available for conduction.

According to one implementation of the invention, the semiconductor body is formed by:
depositing a layer of semiconductor material;
depositing a layer of material selectively etchable relative to the semiconductor material;
patterning the layer of etchable material to substantially correspond to the shape of the at least one horizontal trench to be formed; and

depositing a further layer of semiconductor material,
wherein the access trench formed in step (a) intersects with the layer of etchable material, and step (b) comprises etching away the etchable material.

Such an approach may only require a single photolithographic mask, which is used to pattern the layer of material selectively etchable relative to the semiconductor material of the body.

In a further embodiment, the semiconductor body is formed by:
depositing a layer of semiconductor material;
depositing a plurality of layers of material, alternating between a layer of semiconductor material and a layer of material selectively etchable relative to the semiconductor material, the thickness of the plurality of layers substantially corresponding to the vertical depth of the at least one horizontal trench to be formed;
patterning said plurality of layers of material to substantially correspond to the shape of the at least one horizontal trench to be formed; and
depositing a further layer of semiconductor material, wherein

the access trench formed in step (a) intersects with said plurality of layers, and step (b) comprises etching away said etchable material, and removing the semiconductor material within said plurality of layers.

Where epitaxial fabrication methods impose a limit on the depth of a layer of material selectively etchable relative to the semiconductor material of the body, this approach enables formation of horizontal trenches having a greater dimension in the vertical direction.

In the preceding two implementations referred to above, the semiconductor material of the semiconductor body may be silicon, and the material selectively etchable relative thereto may be silicon germanium, for example. Preferably, the proportion of germanium atoms in the silicon germanium is 15% or greater. In particular, a germanium content of around 25% has been found to allow high quality epitaxial deposition of silicon over such a silicon germanium layer, as well as reliable fabrication of a plurality of alternating layers of silicon and silicon germanium.

In another embodiment of the invention, the step of forming at least one horizontal trench comprises:
forming over the top major surface of the semiconductor body a mask having a window substantially corresponding to the shape of the at least one horizontal trench to be formed; and
introducing a high energy implant into the semiconductor body via the window to form an amorphous layer of semiconductor material at the depth of the at least one horizontal trench to be formed;
   wherein the access trench formed in step (a) intersects with the layer of amorphous material, and step (b) further comprises etching away the amorphous material using an etchant selective between semiconductor material of the semiconductor body in its crystalline and amorphous forms.

If an amorphous layer formed in this way is too wide in the vertical direction, it may be narrowed by reformation of crystalline semiconductor material at its sidewalls by a solid phase epitaxy process.

This technique may be repeated several times with different implantation energies to achieve a desired number of horizontal structures. Furthermore, this approach may include epitaxial deposition of a layer of semiconductor material between these implantation steps, and/or after all such implantations have been carried out, to create deeper horizontal structures in the finished device.

Preferably, the implants comprises an electrically inactive impurity, such as argon, for example. Only a single additional photolithographic mask may be required to create such a structure.

A further preferred method of forming at least one horizontal trench comprises:
forming at least one vertical trench which extends to the depth of the at least one horizontal trench to be formed; and
annealing the semiconductor body in a hydrogen atmosphere such that the open end of the at least one vertical trench closes over to leave a void.

This approach may be particularly suitable for formation of horizontal trenches having a greater vertical dimension, for example when the RESURF inducing structure to be formed includes a field plate.

In a further preferred embodiment, the method includes the steps of:

(d) forming a vertical gate trench in the semiconductor body which extends from its top major surface adjacent the opposite end of the at least one horizontal trench to the access trench;

(e) forming an insulating layer over the bottom and sidewalls of the gate trench; and

(f) depositing material in the gate trench to form a gate electrode.

Such a gate structure may serve to reduce the on-resistance of the device by reducing any additional resistance caused by vertical components of conduction pathways in the device.

Embodiments of the invention will now be described by way of example and with reference to the accompanying schematic drawings, wherein:

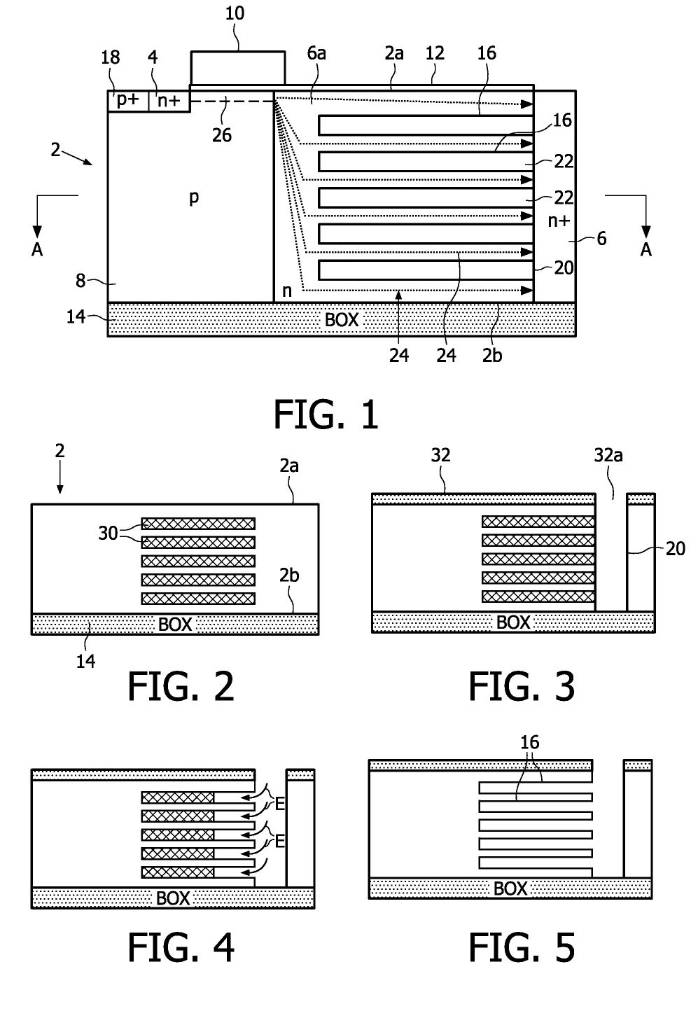

FIG. 1 shows a cross-sectional side view of a lateral semiconductor device manufactured in accordance with a method of the invention;

FIGS. 2 to 5 show cross-sectional side views of a semiconductor body at successive stages in the manufacture of a lateral semiconductor device according to a first embodiment of the invention;

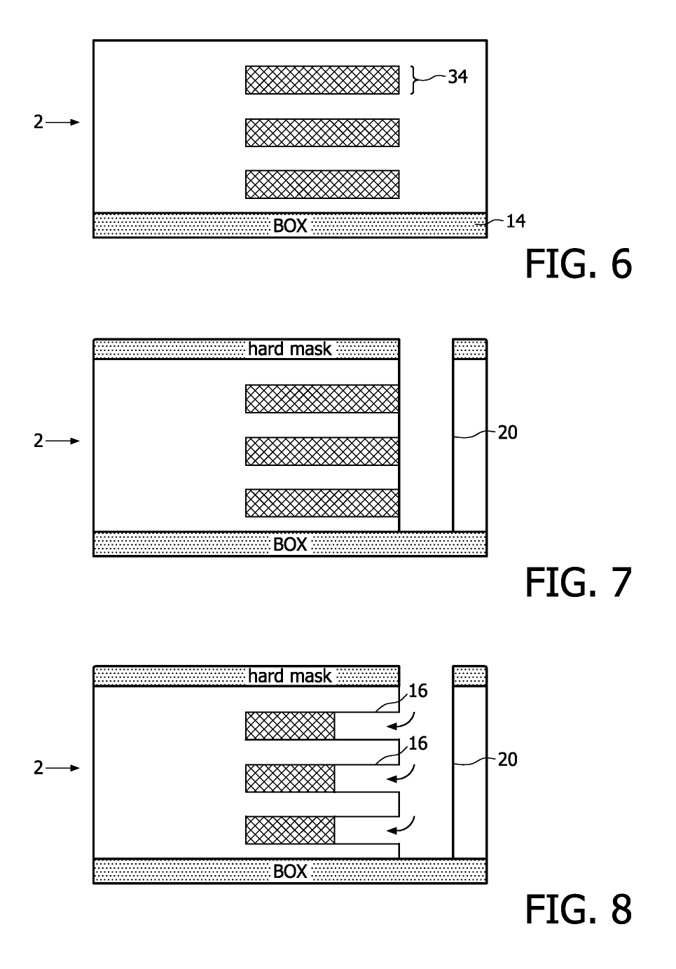

FIGS. 6 to 8 show cross-sectional side views of a semiconductor body at successive stages in the manufacture of a lateral semiconductor device according to a second embodiment of the invention;

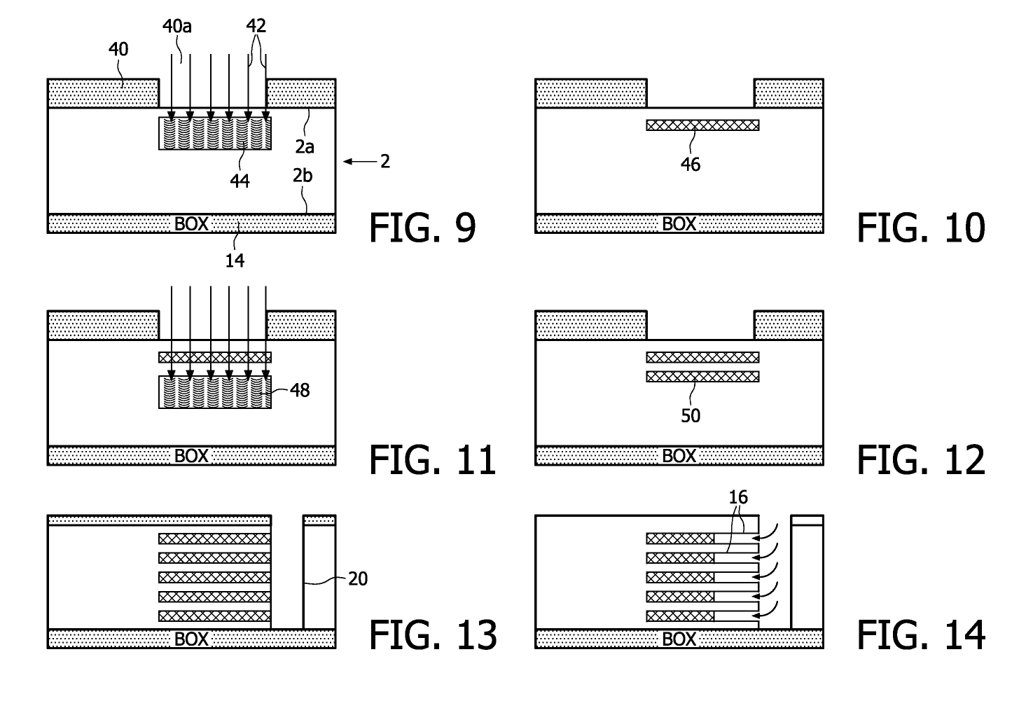

FIGS. 9 to 14 show cross-sectional side views of a semiconductor body at successive stages in the manufacture of a lateral semiconductor device according to a third embodiment of the invention;

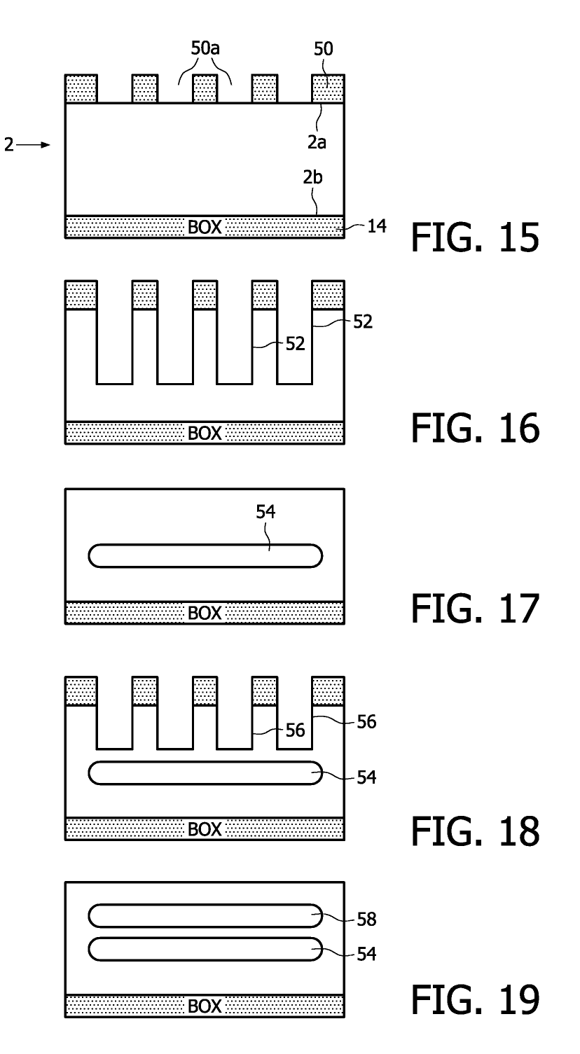

FIGS. 15 to 19 show cross-sectional side views of a semiconductor body at successive stages in the manufacture of a lateral semiconductor device according to a fourth embodiment of the invention;

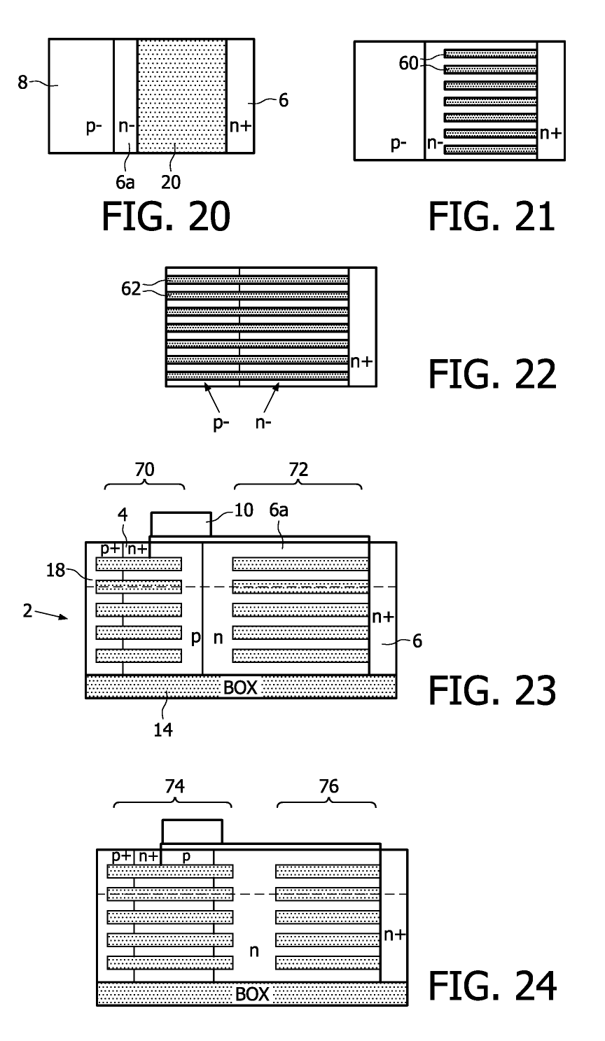

FIGS. 20 to 22 show cross-sectional plan views along the line marked A-A in FIG. 1 showing different configurations of a dielectric RESURF structure;

FIGS. 23 and 24 show cross-sectional side views of a device manufactured in accordance with a method embodying the invention showing further variations in the configuration of a dielectric RESURF inducing structure;

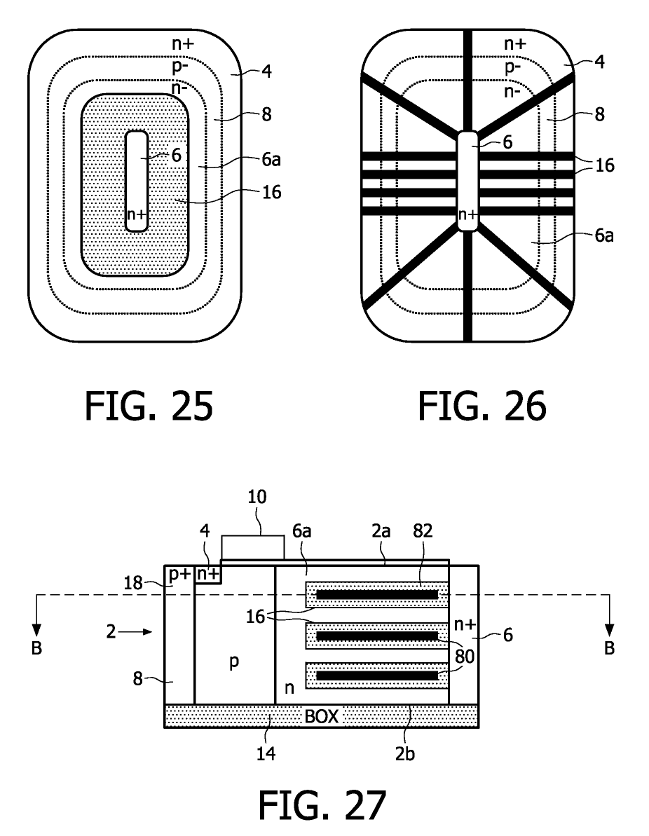

FIGS. 25 and 26 show cross-sectional plan views of the semiconductor body of a device manufactured in accordance with a method embodying the invention including a dielectric RESURF inducing structure;

FIG. 27 shows a cross-sectional side view of a device manufactured by a method embodying the invention, including field plate RESURF inducing structures;

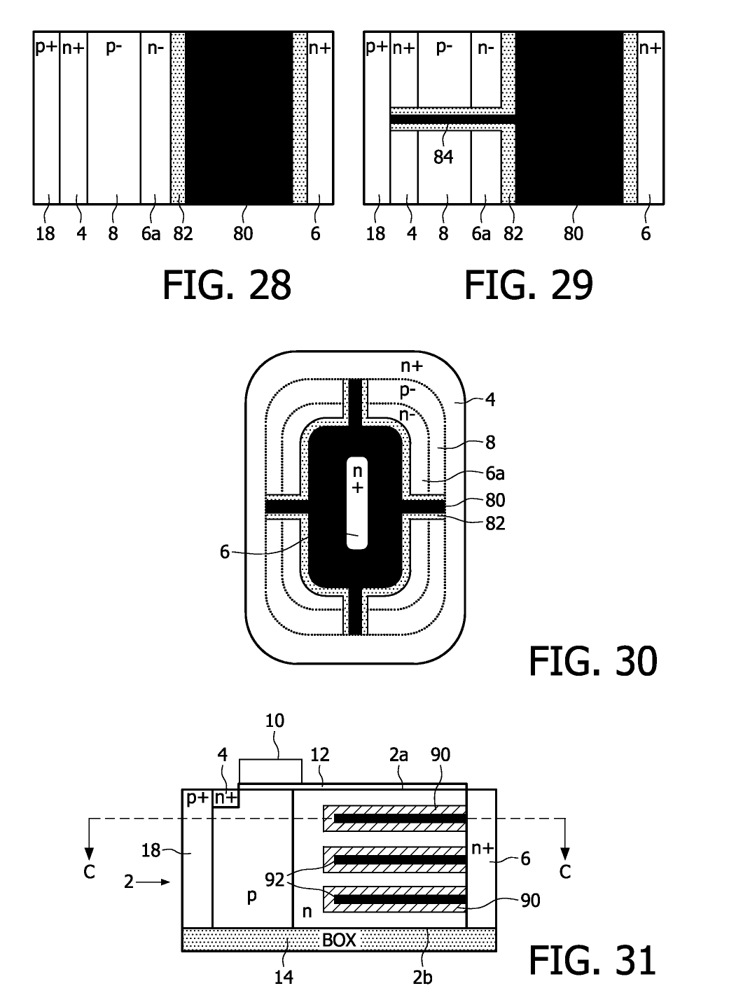

FIGS. 28 and 29 show cross-sectional plan views along the line marked A-A in FIG. 1 showing different configurations of a field plate RESURF structure;

FIG. 30 shows a cross-sectional plan view of the semiconductor body of a device manufactured in accordance with a method embodying the invention including a field plate RESURF inducing structure;

FIG. 31 shows a cross-sectional side view of a device manufactured by a method embodying the invention, including multiple RESURF inducing structures;

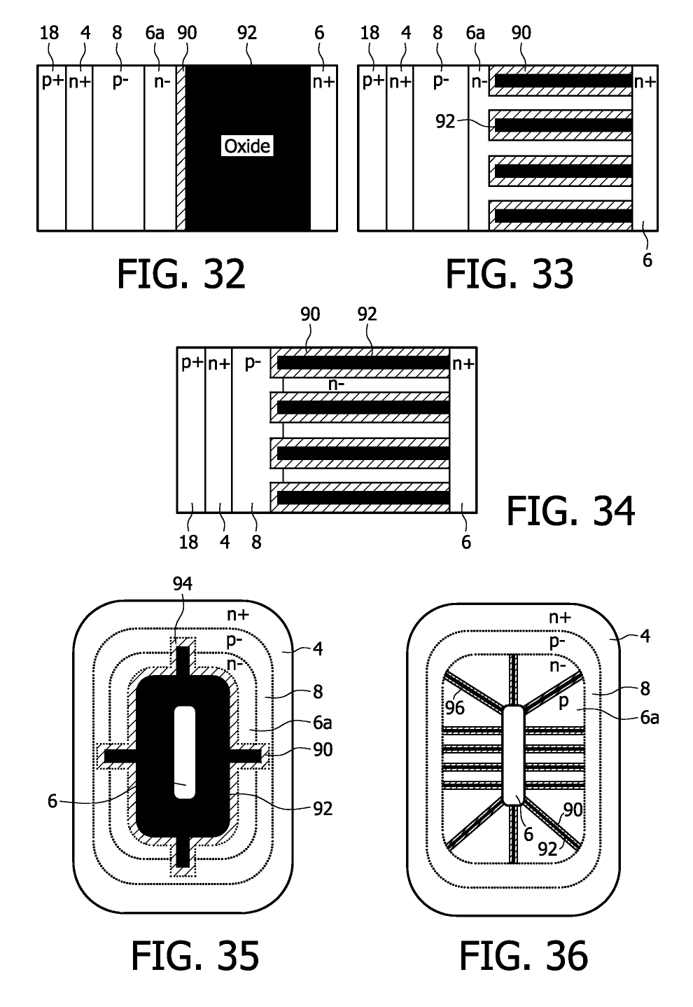

FIGS. 32 to 34 show cross-sectional plan views along the line marked A-A in FIG. 1 showing different configurations of a multiple RESURF structure;

FIGS. 35 and 36 show cross-sectional plan views of the semiconductor body of a device manufactured in accordance with a method embodying the invention including a multiple RESURF inducing structure; and

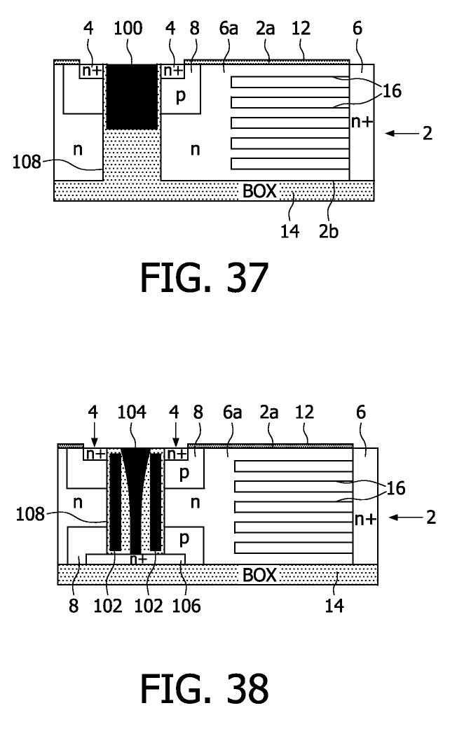

FIGS. 37 and 38 show cross-sectional side views through devices manufactured in accordance with a method of embodying the invention including trenched gate structures.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar features in modified and different embodiments.

A cross-sectional side view of a device manufactured by a method in accordance with an embodiment of the present invention is shown in FIG. 1. In particular, the active area of the device is shown. This active area may be bounded around its periphery by various known peripheral termination schemes (not shown).

The device includes a source region 4, and a drain region laterally spaced therefrom. The drain region consists of a drain drift region 6a alongside a more highly doped drain contact region 6. These regions form part of a semiconductor body 2. The source and drain regions, 4 and 6a, 6, are of a first conductivity type (n-type in this example) and are separated by a channel accommodating body region 8, of the opposite, second conductivity type (that is, p-type in this example).

A gate 10, formed of polysilicon for example, is formed over the top major surface 2a of the semiconductor body 2 and is separated therefrom by a layer 12 of insulating material. The gate extends over a portion of channel 8 which extends to the top major surface 2a.

Semiconductor body 2 is formed on a thick layer of insulating material 14 (for example, as typically used in silicon-on-insulator devices), which may be provided to isolate the device from a semiconductor substrate in which integrated circuits are formed. It may also prevent formation of a pn junction with an underlying substrate and/or extension of the depletion layer into the substrate. RESURF effects are generally based on careful charge balance and the underlying semiconductor may disrupt the RESURF effect.

It will be appreciated that the structures described herein may also be built on standard bulk wafers to form discrete components.

Drain contact region 6 is provided in a trench 20, which extends vertically from the top major surface 2a down to the bottom major surface 2b and the insulating layer 14.

A plurality of horizontal, vertically separated trenches extend horizontally into the drain drift region 6a from the sidewall of trench 20. A RESURF inducing structure 22 is provided within each of these horizontal trenches.

The p+ region 18 is a highly doped p+ region and its purpose is to provide a good contact between p type body region 8 and the source electrode. In the most common operation mode, this p+ region is interconnected with the source n+ region 4 (and thus at a voltage of 0V).

The application of a voltage signal to the gate 10 in the on-state of the device induces a conduction channel 26 in the region 8 and charge carrier flow along paths indicated by dotted arrows 24, which extend in parallel between the horizontal trenches 16 through the drain drift region 6a to the drain contact region 6.

The RESURF inducing structures 22 serve to develop uniform potential distributions along their length across the drain drift region 6a from a drain contact region 6 towards the gate 10, thereby increasing the breakdown voltage of the device.

It will be appreciated that the resistance of the vertical link through the drain drift region 6a connecting to the deeper current paths will increase the resistance of each path. To address this, the resistance of this vertical link may be minimised by higher doping of the region of the drain drift region in which they are formed, minimising its length by reducing the vertical dimension of horizontal trenches 16 and the intervening portions of the drain drift region, or by modifying the structure of the gate (see below).

An embodiment of a method for manufacturing a device of the form shown in FIG. 1 will now be described with reference to FIGS. 2 to 5. Firstly, a stack of layers alternating between silicon and silicon germanium is grown epitaxially over thick insulating layer 14. Each layer of silicon germanium is patterned after its deposition, such that its shape in plan view substantially corresponds to that desired for the horizontal trenches to be formed. In this way, a series of horizontally extending, vertically separated regions 30 of silicon germanium are formed within semiconductor body 2. Depending on the number of cycles involved (that is, the number of buried SiGe layers) and their thickness, a planarization process, such as chemical mechanical polishing (CMP) may appropriate. For example, if only one buried SiGe layer is used, CMP will probably not be needed. However, if more than three layers of SiGe are used, one may well need to planarize the top surface of the semiconductor body.

A layer of masking material is then deposited over the top major surface 2a of the semiconductor body, and then patterned to form a mask 32, defining a window 32a. The masking material may be silicon dioxide, silicon nitride or a combination of both, for example. It is preferable to have silicon dioxide on top of such stack due to generally better selectivity of silicon trench etching processes toward oxides.

An etching process is then carried out to form vertical trench 20, the sidewall of which intersects with each of the horizontal silicon germanium regions 30 at one end thereof. A further etching step (denoted by arrows “E” in FIG. 4) is then carried out using an etchant selective between silicon and silicon germanium, to remove the silicon germanium material from the regions 30 to form horizontally extending trenches 16. This may be a wet or a dry etch process.

For example, for dry etching, combination of CF₄ and O₂ chemistry (e.g. gas flow ratio CF₄/O₂=5:1) at low pressures (below 100 mTorr) and high power (˜800 Watt) has been found to give a good etch rate and selectivity. For a wet etch a combination of ammoniac, peroxide and water (NH₄OH:H₂O₂:H₂O=1:1:5) at a temperature of around 75° C. has given good results.

Once the structure shown in FIG. 5 has been formed, further processing is carried out to incorporate RESURF inducing structures in the trenches 16 as described below. The remaining features of the finished device may be formed using known processing techniques, which will not therefore be described here.

In view of the constraints of current epitaxy fabrication methods, the inventor considers that the approach described above in relation to FIGS. 2 to 5 is most suitable for the formation of relatively narrow (in the vertical direction) horizontal trenches. It has been found that, using this approach, the thickness of the drift channels and the horizontal trenches can be well controlled down to around 10 nm or less. This approach may therefore be readily employed in the formation of multiple RESURF or dielectric RESURF structures in accordance with the invention.

If formation of wider trenches is required, which is likely to be the case where the RESURF structure consists of an insulated field plate, the alternative approach illustrated in FIGS. 6 to 8 may be employed. In this way, trenches around 100 nm or more thick may be formed.

Instead of a single layer of silicon germanium, as shown in FIG. 2, a stack of alternating thin silicon germanium and silicon layers is grown (for example 20 nm silicon germanium and 10 nm silicon) at the desired location of each horizontal trench. In this way, the high stress otherwise likely to develop if a thick silicon germanium layer is formed is released through the thin silicon layers in-between the silicon germanium layers.

Furthermore, the use of thinner silicon germanium layers allows a higher germanium content to be adopted in the layers without developing crystal defects. This in turn gives higher etch selectivity, allowing a higher etch rate to be achieved.

In the etching process shown in FIG. 8, the same etchant may be used as is suggested above in relation to the process step of FIG. 4. As the selectivity of the etchant between silicon and silicon germanium will not be perfect, the thin silicon layers are likely to be removed at the same time as the silicon germanium layers, to form deeper trenches 16. Any remainder of these layers may be removed by an isotropic silicon wet or dry etch.

Another technique embodying the present invention for formation of trenches 16 is illustrated in FIGS. 9 to 14. A layer of masking material is deposited over top major surface 2a, and patterned to form a mask 40 defining a window 40a. The shape of the window 40a substantially corresponds to the shape desired for the horizontal trenches to be formed in the semiconductor body 2.

An impurity is implanted into the semiconductor body 2 via the window 40a with a high dose (for example around 3e14 atoms/cm⁻² or higher) at a reasonably high energy (around 150 KeV or higher) to form a buried amorphous layer 44. The implant used may be argon for example. If the amorphous layer so-formed is too wide in the vertical direction, this dimension may be reduced by a solid phase epitaxy process (at low temperatures of around 500-600° C.), to form a narrow and well confined buried amorphous layer 46, shown in FIG. 10. These steps may be repeated using a higher energy implant as shown in FIGS. 11 and 12 to form a further, deeper amorphous layer 50, and so on to form a plurality of amorphous layers, as shown in FIG. 13.

Then, in a similar manner to FIG. 3 above, a vertical trench 20 is etched into the semiconductor body 2 from its top major surface 2a which intersects with the layers of amorphous material. An etching process is then carried out using an etchant selective between monocrystalline and amorphous silicon (such as an ammoniac peroxide mixture (NH₄OH—H₂O₂—H₂, APM) or HF solution), as shown in FIG. 14.

Another process for forming horizontal trenches at different depths in a semiconductor body for use in a method embodying the invention is illustrated in FIGS. 15 to 19. A technique termed “silicon surface migration effect” is employed, which is described in a paper by Tsumotu Sato et al, entitled “Micro-structure transformation of silicon . . . ”, Jpn. J. Appl. Phys. VOL 39 (2000) pp. 5033-5038. The whole contents of this paper are incorporated herein as reference material. A layer of masking material is formed over the top major surface 2a of the semiconductor body, and patterned to form a mask defining a plurality of windows 50a. The windows 50a are distributed evenly over an area substantially corresponding in shape to that of the trench to be formed. An anisotropic etch process is then carried out to form trenches 52 at each of the windows 50a, which extend to the depth at which the lowermost horizontal trench is to be formed.

As shown in FIG. 17, mask 50 is then removed, and a high temperature, low pressure hydrogen annealing step is carried out, causing the shape of the silicon body and hence the trenches therein to be transformed, leaving a horizontally extending cavity 54. For example, a temperature of 1100° C. and a pressure of 10 Torr may be used for around 600 s.

As illustrated in FIG. 18, the steps of FIGS. 15 to 17 may then be repeated using a shallower trench etch, such that a further annealing process under similar conditions yields a further, shallower horizontally extending cavity 58. This sequence of steps may be repeated several times to create the desired number of cavities.

In a modification of the process shown in FIGS. 15 to 19, a plurality of vertically spaced cavities may be formed in a single annealing step by etching an initial array of trenches which are located more closely together, as described with reference to FIGS. 8 and 9 of the Sato article. Subsequent processing steps are similar to those described for the other embodiments discussed above.

Techniques for the formation of RESURF inducing structures for use in methods embodying the invention will now be described.

Dielectric RESURF structures may be formed in the configuration shown in FIG. 1 by filling horizontal trenches 16 with a dielectric material. The breakdown voltage of the finished device will depend on the thickness of the dielectric layer, the depth of the drain drift region 6a, and the permittivity of the dielectric material.

In one approach, the trenches are filled with silicon dioxide by dry or wet oxidation of the silicon walls of the trenches. Oxide formed in the vertical trench 20 may be removed by an anisotropic etching process before formation of drain contact region 6.

Alternatively, the horizontal trenches may be filled with a high-K material. Suitable materials may be undoped amorphous silicon, or HfO₂, for example. This RESURF technique is disclosed in WO-A-2004/102670 (our ref: PHGB030070), the contents of which are incorporated herein as reference material.

If the high-K material is not resistant to high temperatures, it may be preferable to initially fill or cap trench 20 with a material during high temperature “front-end” processing. Trench 20 may then be re-opened and the high-K material introduced. It may be preferable to spin-on the high-K material. The lower temperature “back-end” processing may then be carried out without affecting the high-K material.

Possible configurations of the dielectric filled horizontal trenches 16 are shown in FIGS. 20 to 22. They illustrate cross-sectional plan views of a device having the configuration shown in FIG. 1, along line A-A. In FIG. 20, the dielectric filled trenches 16 are plate-shaped, and in FIGS. 21 and 22, they comprise a plurality of horizontally and vertically separated pillars 60, 62, respectively.

In FIG. 22, the pillars 62 are shown to extend beyond drain drift region 6a, and into channel-accommodating region 8, beneath channel 26.

Cross-sectional side views through further variations are shown in FIGS. 23 and 24. In each case, the horizontal trenches may be in the form of plates or pillars. In each case, p-type region 18 extends vertically between top and bottom major surfaces 2a, 2b.

In FIG. 23, a first set 70 of vertically separated trenches extends from region 18 and partway across channel-accommodating region 8 towards the drain drift region 6a, whilst a second set 72 extends most of the way across drain drift region 6a from the drain contact region 6. In contrast, in FIG. 24, a first set 74 of vertically separated horizontal trenches extends from p-type region 18 across the channel-accommodating region 8 and into the drain drift region 6a, with a second set 76 extending from drain contact region 6, and partway across drain drift region 6a towards, but spaced from, the first set 74. The spacing or break between sets 70, 72 in FIGS. 23 and 74, 76 in FIG. 24 are appropriate where the trenches have a plate configuration to enable current to flow from the parallel paths formed in the drain drift region to the channel 26. It will be apparent that if the trenches are formed with a pillar configuration, these breaks may not be required.

FIGS. 25 and 26 illustrate exemplary plan layouts for the active areas of devices of the form described above incorporating dielectric filled RESURF inducing trenches. A “plate” trench configuration is shown in FIG. 25, and a “pillar” configuration shown in FIG. 26. In this embodiment, the pillars extend radially outwards from the drain contact region 6 towards the peripheral source region 4.

FIG. 27 shows a cross-sectional side view of a lateral semiconductor device manufactured using a method embodying the invention, in which insulated field plates 80 are provided in respective horizontal trenches 16. Cross-sectional plan views along the line B-B marked in FIG. 27 are shown in FIGS. 28 and 29.

Each field plate may be connected to source potential for example. One way of achieving this is shown in FIG. 29, in which a connection 84 extends from one edge of the field plate, across the channel-accommodating region 8 and source region 4. In some applications, where switching speed is not critical, the field plate may also be connected to the gate.

The access trench network 20, which is used to access and etch the horizontal trenches may be configured in such a way that it receives the connector 84.

Each field plate may have a plate or pillar configuration. Each pillar is connected to a bias potential, such as the source potential for example.

A cross-sectional plan view illustrating exemplary layout of such a device is shown in FIG. 30.

In order to fabricate insulated field plates in a semiconductor body including horizontal trenches 16 and an access trench 20, the following process may be employed.

An oxide is formed on the sidewalls of the trenches using a wet or dry oxidisation process. This is followed by deposition of polysilicon to fill the horizontal trenches to form the field plates and connections 84. It may be preferable to form an access trench at the source side of the horizontal trenches, to facilitate formation of a connection between the source region and the field plates.

FIG. 31 shows a cross-sectional side view through a device including horizontally extending multiple RESURF structures. The sidewalls of the horizontal trenches 16 are doped with a dopant (in this example p-type) of opposite conductivity type to the drain drift region 6a. The horizontal trenches are then filled with a dielectric 92. The dimensions and the doping level of regions 90 are selected such that, when depleted together with adjacent portions of the drain drift region, a voltage-sustaining space-charge zone is formed. That is, when depleted, the space-charge per unit area in the n and p type regions balances at least to the extent that the electric field resulting from the space-charge is less than the critical field strength at which avalanche breakdown would occur.

U.S. Pat. No. 4,754,310 (Our ref: PHB 32740) discloses semiconductor devices with depletable multiple-region (multiple RESURF) semiconductor material comprising alternating p-type and n-type regions which together provide a voltage-sustaining space-charge zone when depleted. The use of such material for the space-charge zone permits the achievement of a lower on-resistance in the device having a given breakdown voltage and is particularly advantageous for a voltage MOSFET device. The whole contents of U.S. Pat. No. 4,754,310 are hereby incorporated herein as reference material.

FIGS. 32 to 34 show cross-sectional views taken along line C-C marked in FIG. 31 to illustrate different embodiments of the structure shown in FIG. 31. In the embodiment of FIG. 32, the multiple RESURF inducing structure has a “plate” configuration, whilst in FIGS. 33 and 34 it has a “pillar” configuration. These Figures differ in that, in FIG. 33, the trenches 16 only extend partway across drain drift region 6a, whilst in FIG. 34, they extend through drain drift region 6a, into channel-accommodating region 8.

Cross-sectional plan views illustrating possible layouts are of the types of devices discussed above in relation to FIGS. 31 to 34 are shown in FIGS. 35 and 36. In each case, p-type connections 94, 96 are shown to extend across the drain drift region 6a to make a connection from each RESURF inducing structure to the p-type channel-accommodating region 8 and through p+ region 18, the ground potential is realised.

After fabrication of a semiconductor body comprising horizontally extending trenches within the drain drift region connecting to an access trench, multiple RESURF inducing structures may be formed as follows. Vapour phase or plasma immersion doping may be used to dope the sidewalls of the trenches 16. The trenches are then filled with a dielectric, or left empty to leave voids in the finished device, and then the device is completed as discussed above.

In order to minimise the increase in on-resistance due to vertical component of current paths formed in the device configurations described herein, the gate may be formed in a trench which extends vertically down from the top major surface of the semiconductor body 2. Two exemplary embodiments of this configuration are shown in FIGS. 37 and 38.

In the embodiment of FIG. 37, a single gate 100 extends downwardly from top major surface 2a to below the channel-accommodating region 8.

In the variation illustrated in FIG. 38, the gate extends over the sidewalls of its trench 108. The trench 108 extends down to a further source region 106 which is formed over insulating layer 14. A connection 104 extends from the top major surface, between and insulated from the gate electrodes 102, to this source region 106 to connect it to the source electrode of the device.

The gate arrangement shown in FIG. 38 may be particularly beneficial if a large number of drift channels are employed (say 8 or more), such that the vertical path for carriers from the lowest channels would be approximately the same as the length of the drift region itself. As drawn in FIG. 38, the carriers from the bottom transistor channel would tend to follow paths through the lower drift channels and the carriers from the upper transistor channel would follow paths through upper drift channels.

It will be evident that many variations and modifications are possible within the scope of the present invention. The particular examples described above are n-channel devices, in which the source and drain regions are of n-type conductivity, the channel-accommodating region is of p-type, and an electron inversion channel 26 is induced in the channel-accommodating region by the gate 10, 100 or 102. By using opposite conductivity type dopants, a p-channel device can be manufactured by a method in accordance with the invention. In this case, the source and drain regions are of p-type conductivity, the channel-accommodating region is of n-type, and a hole inversion channel is induced in the channel-accommodating region by the gate.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination. The Applicants hereby give notice that new Claims may be formulated to such features and/or combinations of such features during the prosecution of the present Application or of any further Application derived therefrom.

1. A method of manufacturing a lateral semiconductor device comprising a semiconductor body having top and bottom major surfaces, the body including a drain drift region of a first conductivity type, wherein the method includes
forming a vertical access trench in the semiconductor body which extends from its top major surface and has a bottom and sidewalls;
forming at least one horizontal trench extending within the drain drift region, which extends from a sidewall of the vertical trench in the finished device; and
forming a RESURF inducing structure extending within the at least one horizontal trench.

2. A method of claim 1 forming at least one horizontal trench comprises forming a plurality of vertically separated horizontal trenches.

3. A method of claim 2 forming at least one horizontal trench comprises forming a plurality of vertically and horizontally separated horizontal trenches.

4. A method of claim 1 wherein the semiconductor body is formed by:
depositing a layer of semiconductor material; depositing a layer of material selectively etchable relative to the semiconductor material;
patterning the layer of etchable material to substantially correspond to the shape of the at least one horizontal trench to be formed; and
depositing a further layer of semiconductor material, wherein the access trench formed in step a intersects with the layer of etchable material, and forming at least one horizontal trench comprises etching away the etchable material.

5. A method of claim 1 wherein the semiconductor body is formed by:
depositing a layer of semiconductor material;
depositing a plurality of layers of material, alternating between a layer of semiconductor material and a layer of material selectively etchable relative to the semiconductor material, the thickness of the plurality of layers substantially corresponding to the vertical depth of the at least one horizontal trench to be formed;
patterning said plurality of layers of material to substantially correspond to the shape of the at least one horizontal trench to be formed; and
depositing a further layer of semiconductor material, wherein the vertical access trench intersects with said plurality of layers, and forming at least one horizontal trench comprises etching away said etchable material, and removing the semiconductor material within said plurality of layers.

6. A method of claim 4 wherein the semiconductor material is silicon and the material selectively etchable relative thereto is silicon germanium.

7. A method of claim 6 wherein the proportion of germanium atoms in the silicon germanium is 15% or greater.

8. A method of claim 1 wherein the step b comprises:
forming over the top major surface of the semiconductor body a mask having a window substantially corresponding to the shape of the at least one horizontal trench to be formed; and
introducing a high energy implant into the semiconductor body via the window to form an amorphous layer of semiconductor material at the depth of the at least one horizontal trench to be formed,
wherein the vertical access trench formed intersects with the layer of amorphous material, and the forming at least one horizontal trench further comprises etching away the amorphous material using an etchant selective between semiconductor material of the semiconductor body in its crystalline and amorphous forms.

9. A method of claim 1 the forming at least one horizontal trench comprises:
forming at least one vertical trench which extends to the depth of the at least one horizontal trench to be formed; and
annealing the semiconductor body in a hydrogen atmosphere such that the open end of the at least one vertical trench closes over to leave a void.

10. A method of claim 1 wherein forming a RESURF structure comprises substantially filling the at least one horizontal trench with a dielectric material.

11. A method of claim 10 wherein forming a RESURF inducing structure comprising oxidizing the walls of the at least one horizontal trench.

12. A method of claim 1 wherein forming a RESURF inducing structure comprises forming a layer of insulating material over the walls of the at least one horizontal trencher; and depositing material in the at least one trench to form a field plate.

13. A method of claim 1 wherein forming a RESURF inducing structure comprises introducing dopant of the second conductivity type into the at least one trench to dope its sidewalls.

14. A method of claim 1 including
forming a vertical gate trench in the semiconductor body which extends from its top major surface adjacent the opposite end of the at least one horizontal trench to the access trench;
forming an insulating layer over the bottom and sidewalls of the gate trench; and
depositing material in the gate trench to form a gate electrode.

15. A lateral semiconductor device manufactured by a method of claim 1.
